(19) United States
(12) Patent Application Publication
(10) Pub. No.: US 2017/0162360 A1
(43) Pub. Date: Jun. 8, 2017

(54) PROCESS FOR TREATING AND RECEPTACLE FOR CONFINING AN ANODE FOR PRODUCING X-RAYS

(71) Applicant: ACERDE, Sainte Helene du Lac (FR)

(72) Inventors: Guillaume Huot, Chambery (FR); Ariane Petitjean, Barraux (FR); Pierre-Olivier Robert, La Ravoire (FR); Gregory Francart, Allevard-Les-Bains (FR); Hervé Poirel, Saint Martin D'Uriage (FR)

(73) Assignee: ACERDE, Sainte Helene du Lac (FR)

(21) Appl. No.: 15/373,316

(22) Filed: Dec. 8, 2016

(30) Foreign Application Priority Data
Dec. 8, 2015 (FR) 1561985

(51) Int. Cl. H01J 35/10; C23C 16/02; C23C 16/06

(52) U.S. Cl. CPC H01J 35/10; C23C 16/06; C23C 16/0272; H01J 2235/085; H01J 2235/086

(57) ABSTRACT

Process for treating and receptacle for confining an anode, wherein the anode is placed in a confining receptacle that envelops this anode while leaving uncovered an annular coating zone of a frontal face of this anode, which is defined by an aperture of the receptacle; in order to carry out a least one operation for treating said annular coating zone, implementing at least one treating gas.

### BACKGROUND

The present invention relates to the field of x-ray emitter devices, especially those used to produce images and more particularly those used in medical imagery scanners.

The production of x-rays is obtained with a refractory material, generally tungsten or an alloy mainly based on tungsten, under the effect of an incident beam of electrons that is directed toward and locally bombards this material.

Commonly, the refractory material takes the form of a target coating (generally made of tungsten-rhenium (W—Re)) formed on a disc made of another material and extending over an annular zone of one face of the disc, the amalgam being called an anode. This anode contains an axial passage for mounting it on the end of a shaft that is used to rotate the anode such that the incident beam of electrons sweeps out an annular track on the target coating made of a refractory material.

The disc may be a single part for example made of graphite or of a molybdenum alloy or comprise a first ring, on one face of which the annular coating is produced, and a second ring brazed to the other face of the first ring. The first ring may be made of a refractory material, for example a molybdenum-based alloy, in particular titanium-zirconium-molybdenum (TZM), or be made of pure molybdenum, the second ring may be made of graphite and the braze joint or layer binding the two rings may be made of a refractory material, for example of zirconium (Zr), titanium (Ti), niobium (Nb), hafnium (Hf), vanadium (V), molybdenum (Mo), tungsten (W), rhenium (Re), tantalum (Ta) or any other refractory alloy or metal.

Generally, in operation, the speeds of rotation of such anodes may reach about 10,000 revolutions per minute. The temperature at the point of impact of the electrons may reach 2000° C., the temperature of the anode, in its bulk, generally stabilizing at about 1300° C.

Such an operation generates high thermomechanical stresses in the anodes. To limit these stresses, these anodes, especially if they are large, may be provided with regularly distributed radial slits that pass axially through the disc and coating and that open radially onto the exterior.

The target coating degrades gradually and more particularly in the annular track or zone swept out by the incident radiation. Various ways of repairing such a coating have been proposed.

To protect the braze joints, it is known to coat the anode with a protective layer everywhere but in the annular zone intended to receive the coating, this protective layer then being removed. However this way of proceeding is tedious and costly.

Patent EP 0 709873 describes a process for treating an annular target coating of an anode, in which the surfaces other than this annular target coating are equipped with a layer forming a protective mask.

### SUMMARY

According to one embodiment, a process is proposed for treating an anode, which may comprise: placing the anode in a confining receptacle, which comprises a platen on which the anode rests, an annular wall protruding with respect to this platen and extending around the peripheral wall of the anode, and a cover placed on a frontal face of the anode, so that said annular wall and said cover define therebetween an annular aperture defining an uncovered annular zone on the frontal face of the anode placed in the receptacle; and carrying out a least one operation for treating said annular coating zone, implementing at least one treating gas.

Thus, everywhere but in the annular coating zone, the anode may be protected during the treating operation with no direct intervention on the anode.

The process may comprise: leaving at least one internal space between the anode and the confining receptacle.

Said internal space may be placed facing an edge of at least one braze joint.

The process may comprise: carrying out said treating operation after a powdered sacrificial protective substance has been introduced into said internal space.

The process may comprise: making a shielding gas flow through said at least one internal space during said treating operation.

Said anode may comprise two superposed rings having therebetween a binding layer, a local surface of the anode including at least one edge of said binding layer defining said internal space.

A confining receptacle able to contain a disc-shaped anode is also provided.

The confining receptacle may comprise a platen on which one of the radial faces of the anode is able to rest; an annular wall protruding with respect to this platen and able to extend around the peripheral wall of the anode, facing the periphery of the anode; and a cover able to be placed on a frontal face of the anode; so that said annular wall and said cover define therebetween an annular aperture defining an uncovered annular zone on the frontal face of the anode placed in the receptacle.

At least one internal local surface of the receptacle may be able to leave at least one internal space between this internal local surface and at least one local surface of the anode placed in the receptacle.

Said internal space may be located facing at least one edge of said binding layer of the anode placed in the receptacle.

Said internal space may be able to receive a powdered protective substance.

The confining receptacle may comprise at least one orifice for admitting gas into said internal space and an orifice for exhausting this gas.

The confining receptacle may comprise internal means for centring the anode radially on said platen.

The cover may have a radially centring portion able to interact with a radially centring portion of the anode.

Said annular wall may comprise a cylindrical wall protruding with respect to the platen and an annulus able to be placed on the edge of this cylindrical wall.

The confining receptacle may comprise a cup including said platen and at least partially said annular wall.

The platen may comprise grooves bringing into communication a central internal space and a peripheral annular internal space.

Said grooves may be located below radial slits in the anode placed on said platen.

The confining receptacle may comprise an orifice for emitting a gas into a central internal space.

Said annular wall may comprise a lower annular portion that is securely fastened to the platen and an upper annular portion able to rest on the lower annular portion.

### DESCRIPTION OF THE DRAWINGS

The foregoing aspects and many of the attendant advantages of this invention will become more readily appreciated as the same become better understood by reference to the following detailed description, when taken in conjunction with the accompanying drawings, wherein:

FIG. 1 shows, in perspective, an anode able to produce x-rays;

FIG. 2 shows an exploded cross-sectional view of a confining receptacle able to receive the anode in FIG. 1;

FIG. 3 shows a cross-sectional view of a portion of the confining receptacle, holding the anode in FIG. 1;

FIG. 4 shows a cross-sectional view of the assembled confining receptacle containing the anode in FIG. 1;

FIG. 5 shows a top view of FIG. 4;

FIG. 6 shows a cross-sectional view of another confining receptacle containing another anode;

FIG. 7 shows a cross-sectional view of another assembled confining receptacle containing the anode in FIG. 1;

FIG. 8 shows an angularly shifted cross-sectional view of the confining receptacle in FIG. 7; and

FIG. 9 shows a downward perspective view of a portion of the confining receptacle in FIG. 7.

### DETAILED DESCRIPTION

Confining receptacles and their modes of use will now be described by way of nonlimiting examples, which examples are illustrated by the FIGURES.

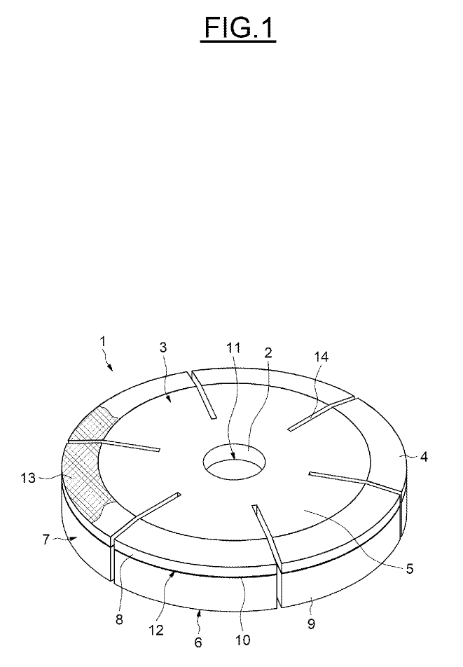

According to one embodiment, a disc-shaped rotary circular anode 1 for producing x-rays, which anode is illustrated in FIG. 1, comprises a cylindrical central axial mounting passage 2 able to receive one end of a shaft (not shown) that is used to rotate the anode.

The anode 1 has a frontal face 3 that comprises a slightly frustoconical annular zone 4 located around a radial central zone 5 passed through by the central passage 2, and that has a radial back face 6 and a cylindrical peripheral field or face 7.

The anode 1 is composed of a first ring 8 and a second ring 9, which are superposed and fastened to each other by way of a radial binding layer 10. The first ring 8 has the frontal face 3. The second ring 9 has the back face 6. The peripheral fields or faces of the rings 8 and 9 constitute the cylindrical face 7 of the anode 1. The radial binding layer 10 has an annular internal edge 11 contained in the wall of the central passage 2 and an annular external edge 12 contained in the cylindrical peripheral field 7.

The first ring 8 is made of a refractory material, for example of an alloy based on molybdenum, in particular titanium-zirconium-molybdenum (TZM), or of pure molybdenum.

The second ring 9 is made of graphite.

The radial binding layer 10 is formed by a brazed joint made of a refractory material, for example made of zirconium (Zr), titanium (Ti), niobium (Nb), hafnium (Hf), vanadium (V), molybdenum (Mo), tungsten (W), rhenium (Re), tantalum (Ta) or another refractory alloy or metal.

In the annular zone 4 of the frontal face 3 a target coating 13 is present that comprises at least one material able to produce x-rays under the effect of an incident beam of electrons. In use, during the rotation of the anode 1, the point of impact of the incident beam of electrons describes an annular local track on the coating.

The coating 13 of the annular zone 4 may comprise a layer or a stack of layers, for example of tungsten or an alloy mainly comprising tungsten, for example tungsten-rhenium, formed by sintering or resulting from chemical vapour deposition (CVD).

Furthermore, the anode 1 comprises a plurality of slits 14 that are open axially on both sides and radially onto the exterior, these slits 14 extend axially through the rings 8 and 9, the binding layer 10 and the coating 13 and radially from a point located between the central passage 2 and as far as the peripheral surface 7.

The slits 14 are angularly distributed and serve to limit mechanical stresses during use of the anode 1. Their number may depend on the diameter of the anode 1 and may be equal to three or to a multiple of three.

A confining receptacle 15 able to contain the anode 1, with the aim of carrying out a treatment of the latter while especially protecting the braze joint 10, will now be described.

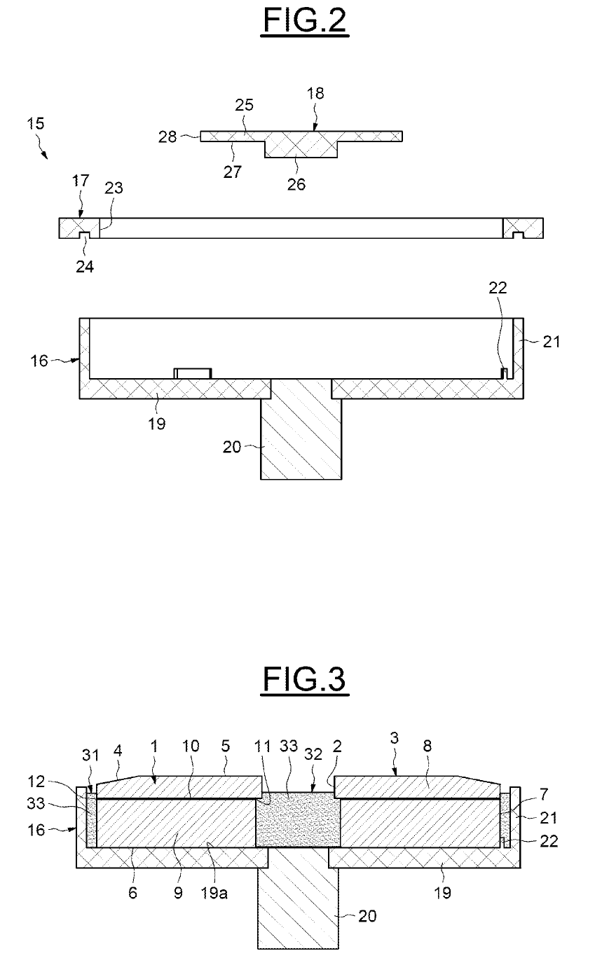

As illustrated in FIG. 2, the confining receptacle 15 comprises, in the form of a kit, a cup 16, a circular annulus 17 and a circular cover 18.

The cup 16 comprises a horizontal radial platen 19, which is mounted on the upper end of a vertical shaft 20 of a depositing machine (not shown), and a cylindrical sidewall 21 protruding upward from the peripheral edge of the platen 19. In the interior of the cup 16, provision is for example made for three protruding studs 22 that serve to centre the anode 1, said studs being located in the vicinity of the cylindrical wall 21 and distributed angularly at 120°.

According to one variant embodiment, the cup 16 could comprise two separable portions, one being formed by the platen 19 and the other being formed by the cylindrical wall 21. For example, the cylindrical wall 21 could be placed and adjusted on the peripheral edge of the platen 19 by virtue of complementary guide flanges.

The circular annulus 17 is for example of rectangular cross section and has a cylindrical internal face 23. This annulus 17 comprises an annular centring groove 24 in one of its radial faces. The circular annulus 17 may be installed on the edge of the cylindrical wall 21 away from the platen 19 by engaging this edge into the annular groove 24.

The cover 18 comprises a circular plate 25 and comprises a cylindrical central centring protrusion 26 protruding from one side of this plate 25, such that the cover 18 has a radial annular face 27 encircling the protrusion 26.

The confining receptacle 15 may be used in the following way.

As illustrated in FIG. 3, the anode 1 is placed in the interior of the cup 16 such that the back face 6 of the anode 1 bears against a face 19a of the platen 19 and such that the centring studs 22 are adjacent to the peripheral face 7 of the anode 1. Thus, the anode 1 is centred and rests on the platen 19, and the cylindrical wall 21 is away from the cylindrical peripheral face 7 of the anode 1.

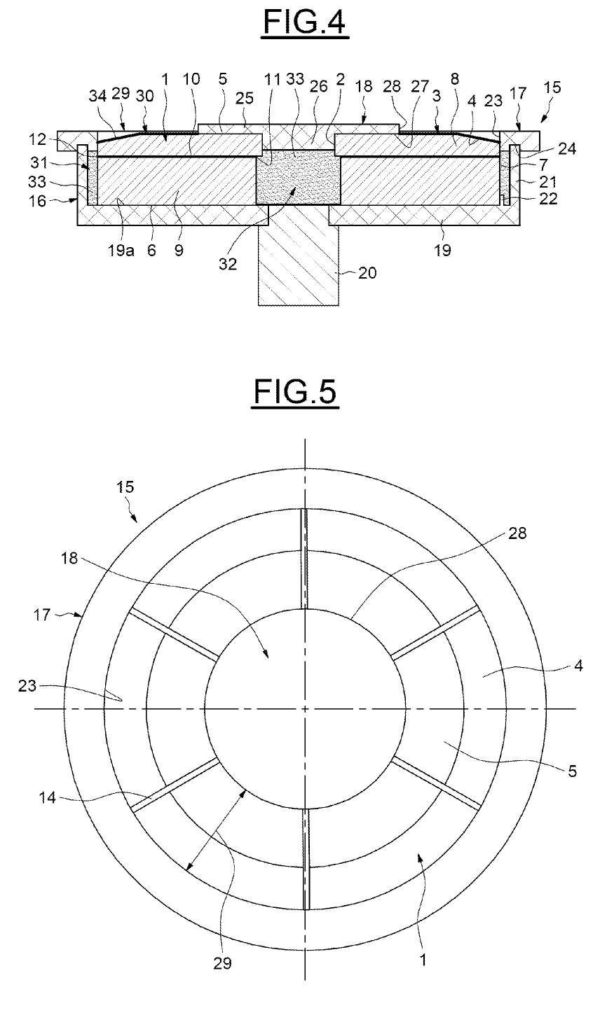

Next, as illustrated in FIGS. 4 and 5, the circular annulus 17 and the cover 18 are fitted as described below.

The circular annulus 17 is placed on the edge of the cylindrical wall 21 of the cup 16, by engaging this edge in the groove 24 of the circular annulus 17, the circular annulus 17 fitting around the upper portion of the cylindrical peripheral face 7 of the anode 1, away from and above the external edge 12 of the binding layer 10 of the anode 1, and extending upward there beyond. In this position, the internal cylindrical face 23 of the circular annulus 17 lies at a distance that is as small as possible from the cylindrical peripheral face 7 of the anode 1. Thus, the cylindrical wall 21 of the cup 16 and the circular annulus 17 constitute a peripheral wall encircling the anode 1. Nevertheless, the circular annulus 17 could have an interior annular rim lying above the peripheral portion of the front face 3 of the anode 1, this rim possibly even making contact with this peripheral portion.

The cover 18 is placed on the anode 1 by engaging its centring protrusion 26 in the central passage 2 of the anode 1, until the radial annular face 27 of the cover 18 rests on the radial central zone 5 of the frontal face 3 of the anode 1. In this position, the peripheral edge 28 of the cover 18 is located between the central passage 2 and the interior edge of the frustoconical annular zone 4 of the anode 1. Thus, the confining receptacle 15 comprises an annular aperture 29 between the circular annulus 17 and the circular cover 18.

As a result of the above assembly, the confining receptacle 15 completely envelops the anode 1 except in an annular coating zone 30 of the front face 3 of the anode 1, which remains uncovered and which corresponds to the annular aperture 29, this annular coating zone 30 containing the frustoconical annular zone 4 that may be equipped with the coating 13 of the anode 1.

The confining receptacle 15 defines an annular internal space 31 that extends radially between the cylindrical wall 21 of the cup 16 and the peripheral face 7 of the anode 1 and axially between the platen 19 and the annulus 17. Thus, in the annular internal space 31 is defined between the internal surfaces of the confining receptacle 15 and a local peripheral surface of the peripheral face 7 of the anode 1 including the external edge 12 of the binding layer 10.

The confining receptacle 15 also defines a central internal space 32 in the central passage 2 of the anode 1, axially between the platen 19 of the cup 16 and the cover 18 placed on the anode 1. The internal edge 11 of the binding layer 10 of the anode 1 is located between the platen 19 and the protrusion 26 of the cover 18. Thus, the central internal space 32 is defined between the internal surfaces of the confining receptacle (the platen 19 and the protrusion 26 of the cover 18) and a local internal surface of the wall of the central passage 2 of the anode 1 including the internal edge 11 of the binding layer 10.

The cup 16, the circular annulus 17 and the circular cover 18, which constitute the confining receptacle 15, may be made of graphite.

One mode of the use of the confining receptacle 15 will now be described.

Having placed the anode 1 in the cup 16 as described above with reference to FIG. 3, a powdered protective substance 33 is deposited in the still open annular space 31 encircling the anode 1, in the slits 14 in the anode 1 and in the still open central passage 2 of the anode 1.

This substance is of the same nature as the material forming the binding layer 10, or the corresponding oxide.

Next, the annulus 17 and the cover 18 are fitted as described above with reference to FIGS. 4 and 5.

The internal spaces 31 and 32 and the slits 14 are then preferably completely filled with this powdered protective material 33.

Next, the confining receptacle 15 containing the anode 1 is placed in a treating chamber so as to produce a coating layer 34 on the coating zone 30 through the aperture 29 of the receptacle 15.

The coating layer 34, which may comprise a plurality of superposed sublayers, may be produced by chemical vapour deposition (CVD). This coating layer 34 comprises a refractory material able to produce x-rays under the effect of an incident beam, generally tungsten (W) or an alloy based mainly on tungsten, for example a tungsten-rhenium alloy (W—Re).

Because the confining receptacle 15 envelops the anode 1 and because of the existence of the powdered substance 33, which is specifically made of a material able to absorb and react with the treating gases, the binding layer 10 of the anode 1 is protected from attack, by the treating gases, from its edges 11 and 12, the powdered substance 33 constituting a sacrificial powder. Furthermore, the surfaces of the anode 1, other than the coating zone 30, are protected from inopportune depositions during the aforementioned treating operation.

Once the coating layer 34 has been produced, the cover 18 is separated, the annular band 17 is separated, the anode 1 is extracted from the cup 17 and the powdered protective substance 33 is removed.

The anode 1 may then be treated so as, optionally, to preserve the coating layer 34 only on the frustoconical peripheral zone 4, to clean the slits 14 of any substances and to grind the surface of the coating layer 34 in this frustoconical peripheral zone 4.

The aforementioned coating 13 may be the first coating produced on the frontal face of the ring 8, or a damaged prior coating 13 may be repaired by virtue of a coating 34 produced on top of this prior coating. A process for repairing a coating implementing chemical vapour deposition (CVD) is in particular described in patent EP-A-2915900.

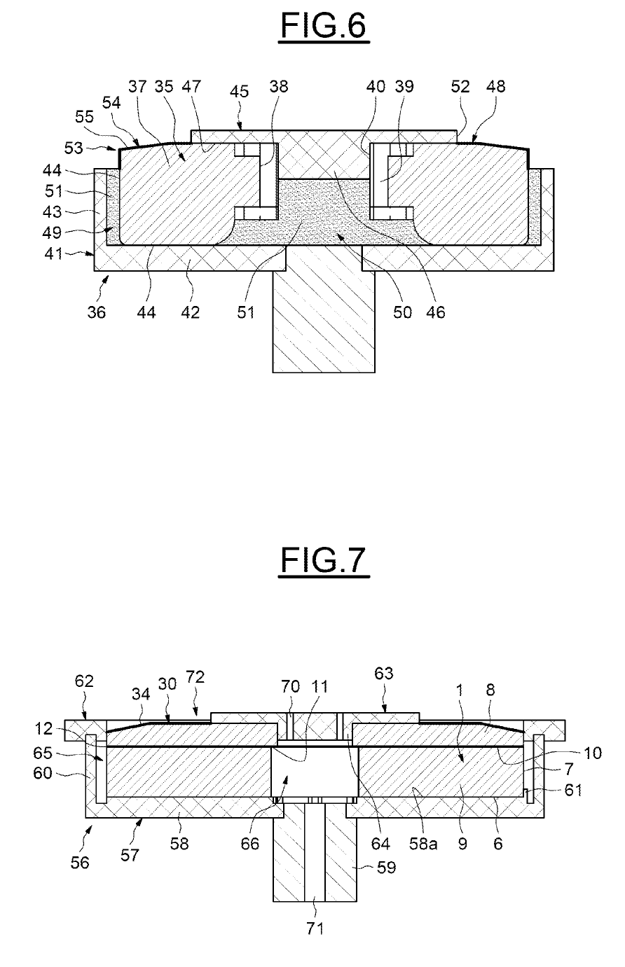

According to another embodiment illustrated in FIG. 6, a circular anode 35 is placed in a confining receptacle 36.

The circular anode 35 comprises a solid unitary disc 37, which is for example made of graphite, this disc having a central passage 38 to which a metal insert 39 defining a cylindrical central mounting passage 40 is fastened. This insert may be fastened by braze joints.

The confining receptacle 36 comprises a cup 41 that is equivalent to the cup 16 and that comprises a horizontal radial platen 42 and a cylindrical wall 43 protruding from the peripheral edge of the platen 42.

The anode 35 is placed in the cup 41 so that its back radial face 44 rests on the platen 42 and so that the cylindrical wall 43 extends around the cylindrical peripheral face 44 of the disc 37 while remaining a distance away from said face.

The confining receptacle 36 furthermore comprises a cover 45 that is equivalent to the cover 18 and that comprises an axial protrusion 46, which is engaged in the central passage 40 of the insert 39, and a radial annular face 47 encircling the protrusion 46 and bearing against the interior annular portion of the frontal face 48 of the anode 35.

In contrast to the preceding embodiment, the annulus 17 is not present. Equivalently to the preceding embodiment, the annular space 49 between the cylindrical peripheral face 44 of the anode 35 and the cylindrical wall 43 of the cup 41, and the central space 50 of the anode 35 between the platen 42 and the protrusion 46 of the cover 45 are filled with a powdered protective substance 51 that is equivalent to the powdered protective substance 33. This powdered substance 51 is introduced after the anode 35 has been placed in the cup 41 and before the cover 45 is fitted on the anode 35.

The peripheral edge 52 of the cover 45 and the powdered substance 51 introduced into the peripheral space 49 define an annular aperture 53 to which a coating zone 54 on the frontal face 48 of the anode 35 corresponds, this coating zone 53 being equivalent to the coating zone 30 of the preceding embodiment.

The coating zone 54 may be treated equivalently to the preceding embodiment, to produce an annular coating layer 55 equivalent to the annular coating layer 34.

Thus, equivalently to the preceding embodiment, because the confining receptacle 36 envelops the anode 35 and because of the existence of the powdered material 51, which is specifically made of a material able to absorb and to react with the treating gases, the braze joints of the insert 39 on the disc 37 are protected from attack by the treating gases, the powdered substance 51 constituting a sacrificial powder, and the surfaces of the anode 35, other than the coating zone 54, are protected from inopportune depositions during the aforementioned treating operation.

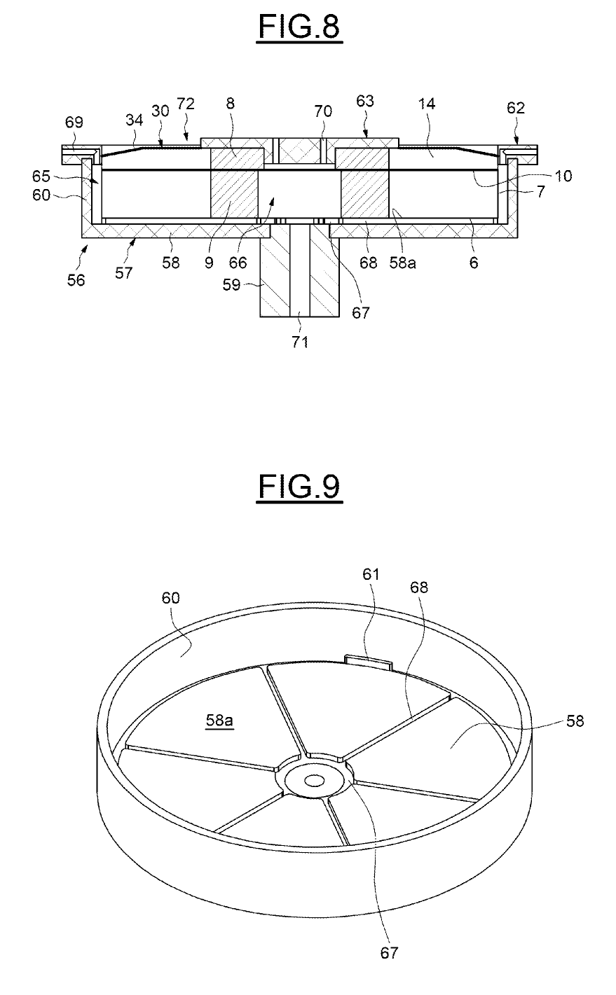

According to another embodiment illustrated in FIGS. 7, 8 and 9, a confining receptacle 56 is also intended to contain the circular anode 1 shown in FIG. 1.

Equivalently to the confining receptacle 15, this confining receptacle 56 comprises a cup 57, which comprises a platen 58 mounted on the upper end of a shaft 59 of a depositing machine (not shown) and a cylindrical wall 60 and in which the anode 1 may be placed, the back face 6 of the anode 1 bearing against a face 58a of the platen 58 and the anode 1 being centred by protruding studs 61.

The confining receptacle 56 also comprises a circular annulus 62 intended to be placed on the edge of the cylindrical wall 60 of the cup 57, and a circular cover 63 intended to be placed on the central portion of the frontal face 3 of the anode 1 in order to close the central passage 2 of this anode 1, the cover 63 comprising a centring protrusion 64 intended to be engaged in the central passage 2 of the anode 1.

Equivalently to the confining receptacle 15, the following are thus defined: an annular internal space 65 around the peripheral face 7 of the anode 1 and a central internal space 66 in the central passage 2 of the anode 1, the annular internal space 65 and the central internal space 66 being equivalent to the internal spaces 31 and 32 defined by the confining receptacle 15.

The confining receptacle 56 differs from the confining receptacle 15 in that the platen 58 comprises, in its bearing face 58a, a central void 67 and a plurality of radial grooves 68 extending under the anode 1 and which, when the anode 1 is placed on this bearing face 58a of the platen 58, bring the annular internal space 65 and the central internal space 66 into communication.

Furthermore, the circular annulus 62 comprises a plurality of exhausting through-orifices 69 bringing the annular internal space 65 into communication with the exterior, and the cover 63 comprises a plurality of through-orifices 70 bringing the central internal space 66 into communication with the exterior. In addition, the shaft 59 comprises an admitting axial channel or orifice 71 allowing the central internal space 66 to be connected to a source of pressurized gas.

When the confining receptacle 56 containing the anode 1 is placed in a treating furnace, with the aim of producing a coating 34 through the annular aperture 72 provided between the annulus 62 and the cover 63, a neutral shielding gas is injected into the central internal space 66 via the axial channel 71 of the shaft 59.

The shielding gas escapes from the central internal space 66 via the through-orifices 70 in the cover 63.

Furthermore, the shielding gas flows through the grooves 68 in the platen 58 and is thus injected into the annular internal space 65, from which it escapes via the through-orifices 69 in the circular annulus 62. The shielding gas may also escape through any gaps between the circular annulus 62 and the anode 1 and between the cover 63 and the anode 1.

In addition, the radial grooves 68 in the platen 58 and the radial slits 14 in the anode 1 being separated by the same angular spacings and care having been taken to place the slits 14 in the anode 1 above these grooves 68, the shielding gas also flows through the slits 14 in the anode 1 and escapes to the exterior through the aperture 72 and/or flows into the annular internal space 65.

The pressure of the injected shielding gas and the dimensions of the grooves 68 and of the through-orifices 69 and 70 are such that the above flows are possible and oppose the penetration of the treating gases into the internal spaces 65 and 66.

Thus, the binding layer 10 of the anode 1 is protected from attack, by the processing gases, from its edges 11 and 12 and the surfaces of the anode 1, other than the coating zone 30, are protected from inopportune depositions during the operation for producing the coating layer 34.

According to another embodiment, the confining receptacle 36 could comprise measures equivalent to those of the confining receptacle 56. Thus, the platen 42 of the cup 41 could comprise grooves for bringing the internal spaces 49 and 51 into communication and the cover 45 could comprise through-orifices, these internal spaces then possibly being supplied with a shielding gas via a channel in the shaft bearing the platen 42.

According to another embodiment, the examples described above could be combined, for example a powdered protective substance could be placed in said internal spaces and a shielding gas made to flow through these internal spaces.

According to another embodiment, the one or more internal spaces of the confining receptacle could be very small or inexistent.

According to another embodiment, the anode to be treated could not comprise any braze joints.

According to another embodiment, the confining receptacle could be used for another type of anode treatment different from the aforementioned.

According to another embodiment, the confining receptacle could be applied to an anode not having a central through-passage, and in particular to an anode having a blind cylindrical central hole that opens opposite its frontal face. In this case, the radial central protrusion 19 of the cover 18 could be engaged in a radially centring blind central void provided in the frontal face of such an anode. According to one variant embodiment, the anode could have a protruding central protrusion engaged in a radially centring blind central void in the cover.

While illustrative embodiments have been illustrated and described, it will be appreciated that various changes can be made therein without departing from the spirit and scope of the invention.

1. A process for treating a disc-shaped anode for producing x-rays, comprising:
placing the anode in a confining receptacle that comprises a platen on which the anode rests, an annular wall protruding with respect to the platen and extending around the peripheral wall of the anode, and a cover placed on a frontal face of the anode, so that said annular wall and said cover define therebetween an annular aperture defining an uncovered annular zone on the frontal face of the anode placed in the receptacle; and
carrying out a least one operation for treating said annular zone, implementing at least one treating gas.

2. The process according to claim 1, comprising: leaving at least one internal space between the anode and the confining receptacle.

3. The process according to claim 2, wherein said internal space is placed facing an edge of at least one braze joint.

4. The process according to claim 2, comprising: carrying out said treating operation after a powdered sacrificial protective substance has been introduced into said internal space.

5. The process according to claim 2, comprising: making a shielding gas flow through said at least one internal space during said treating operation.

6. The process according to claim 1, wherein said anode comprises two superposed rings having therebetween a binding layer and wherein a local surface of the anode including at least one edge of said binding layer defines said internal space.

7. A confining receptacle able to contain a disc-shaped anode for producing x-rays, comprising:
a platen on which one of the radial faces of the anode is able to rest;
an annular wall protruding with respect to the platen, extending around a peripheral wall of the anode, facing a periphery of the anode; and
a cover configured to be placed on a frontal face of the anode;
wherein said annular wall and said cover define therebetween an annular aperture defining an uncovered annular zone on a frontal face of the anode placed in the confining receptacle.

8. The receptacle according to claim 7, wherein at least one internal local surface of the receptacle is able to leave at least one internal space between this internal local surface and at least one local surface of the anode placed in the receptacle.

9. The receptacle according to claim 8, wherein said internal space is located facing at least one edge of said binding layer of the anode placed in the receptacle.

10. The receptacle according to claim 8, wherein said internal space is able to receive a powdered protective substance.

11. The receptacle according to claim 8, wherein said internal space is able to receive a powdered protective substance.

12. The receptacle according to claim 7, comprising internal means for centring the anode radially on said platen.

13. The receptacle according to claim 7, wherein the cover has a radially centring portion able to interact with a radially centring portion of the anode.

14. The receptacle according to claim 7, wherein said annular wall comprises a cylindrical wall protruding with respect to the platen and an annulus able to be placed on the edge of this cylindrical wall.

15. The receptacle according to claim 7, comprising a cup including said platen and at least partially said annular wall.

16. The receptacle according to claim 7, wherein the platen comprises grooves bringing into communication a central internal space and a peripheral annular internal space.

17. The receptacle according to claim 16, wherein said grooves are located below radial slits in the anode placed on said platen.

18. The receptacle according to claim 7, comprising an orifice for emitting a gas into a central internal space.

19. The receptacle according to claim 7, wherein said annular wall comprises a lower annular portion that is securely fastened to the platen and an upper annular portion able to rest on the lower annular portion.
